(19) United States
(12) Patent Application Publication
(10) Pub. No.: US 2005/0066896 A1
(43) Pub. Date: Mar. 31, 2005

(54) Apparatus for treating the outer surface of a metal wire

(76) Inventor: Wolfgang Viol, Adelebsen (DE)

Correspondence Address: Scott A. Horstemeyer;THOMAS, KAYDEN, HORSTEMEYER & RISLEY, L.L.P., Suite 1750, 100 Galleria Parkway, Atlanta, GA, 30339, US

(21) Appl. No.: 10/975,704

(22) Filed: Oct. 28, 2004

(30) Foreign Application Priority Data
Jan. 9, 2003 (DE) 103 00 471.8
Apr. 29, 2002 (DE) 102 190197.2-14

(51) Int. Cl. C23C 16/00

(52) U.S. Cl. 118/718

(57) ABSTRACT

An apparatus for treating the outer surface of a metal wire being moved through the apparatus along a direction of longitudinal extension of the metal wire has two electrodes arranged at a distance in the direction of longitudinal extension of the metal wire, a gas room being arranged between the outer surface of the metal wire to be treated and said electrodes, a dielectric shielding for said electrodes shielding said electrodes towards the metal wire, and an alternating voltage generator generating an alternating high voltage between said two electrodes to provide a dielectric barrier discharge in said gas room above the outer surface of the metal wire. The metal wire serves as an intermediate electrode between said two electrodes.

### CROSS REFERENCE TO RELATED APPLICATIONS

This application is a continuation in part of International Patent Application PCT/EP2003/003509 filed Apr. 4, 2003, entitled “Verfahren und Vorrichtung zur Behandlung der äuβeren Oberfläche eines Metalldrahts, insbesondere als Beschichtungsvorbehandlung” and claiming priority to co-pending German Patent Applications Nos. 102 19 197.2 filed Apr. 29, 2002 and entitled “Verfahren und Vorrichtung zur Behandlung der Oberfläche eines Metalldrahts, insbesondere als Beschichtungsvorbehandlung”, and 103 00 471.8 filed Jan. 9, 2003 and entitled “Verfahren und Vorrichtung zur Behandlung der äuβeren Oberfläche eines Metalldrahts, insbesondere als Beschichtungsvorbehandlung”.

### FIELD OF THE INVENTION

The present invention generally relates to an apparatus for treating the outer surface of a metal wire, especially as a coating pre-treatment. Particularly the invention relates to an apparatus for treating the outer surface of a metal wire, the apparatus having an electrode, a dielectric shielding for the electrode, the dielectric shielding delimiting a gas room arranged above the outer surface of the metal wire to be treated, and having an alternating voltage generator which applies an alternating high voltage to the electrode.

### BACKGROUND OF THE INVENTION

Metal wires of a defined diameter are made by drawing. In this process, lubricants are used which remain on the surface of the drawn metal wires. If such a drawn wire is to be coated with other metals or plastics, for example, the lubricant remainders have to be removed first. According to the present practice, this is done in alkaline baths. Renewing and disposing these alkaline baths are very expensive. Further, alkaline baths require a high industrial effort.

An apparatus for increasing the wettability of work pieces with liquids by means of a surface pre-treatment with electrical discharge is described in European Patent 0 761 415. In this apparatus, a directional beam of a reactive medium is produced by plasma discharge under supply of a working gas, and the surface of the work piece to be treated is scanned with this beam. The plasma discharge takes place in a plasma nozzle between a pin electrode coaxially extending into the plasma nozzle from behind, and a ring electrode delimiting the nozzle opening, an alternating high voltage in the range of 5 to 30 kV and having a frequency in the order of 20 kHz being applied between the pin electrode and the ring electrode. The directional beam of the reactive medium emerges through the nozzle opening. Work pieces treated by means of the known apparatus may be metallic work pieces. The known apparatus, however, is little suited for treating metal wires because of their geometry. To increase the wettability of the surface of a metal wire which comprises lubricant remainders at its surface, these lubricant remainders have to be removed first. This is not realized by simply scanning the surface of the metal wire with a directional beam produced by the known apparatus.

An apparatus for plasma treating rod- or thread-shaped materials in which the respective material coaxially runs through a plasma nozzle is known from European Patent Application published as EP 0 994 637 A2. The plasma nozzle has a nozzle tube forming an outer electrode and an inner electrode coaxially arranged within the nozzle tube. The rod- or thread-shaped material is introduced into the interior of the plasma nozzle through a hole coaxially formed within the inner electrode. The hole in the inner electrode is lined with a guiding tube for the rod- or thread-shaped material, which guiding tube is made of electrically isolating material. This known apparatus is told to be also suitable for plasma treating wires. In case of wires made of electrically conductive material, i.e. particularly in case of metal wires, however, the plasma nozzle would be shorted out between the inner electrode and the outer electrode by the wire extending from the hole in the inner electrode so that no more plasma discharge would occur. It has to be considered here that the voltage applied between the outer electrode and the inner electrode for producing the plasma discharge is a high frequency alternating high voltage for which a local isolation of the rod- or thread-shaped material in the area of the inner electrode by means of the guiding tube is not sufficient to avoid a short circuit between the inner electrode and the outer electrode which tends to occur because of the metal wire.

Even with a metal wire which is already provided with a conductive or a non-conductive coating, such as, for example, an isolation coating, it becomes evident that a pre-treatment of the coating prior to a further coating or prior to printing on the coating, for example, indications of the type or the producer of the wire by means of an inkjet printer, cannot be avoided.

An apparatus for treating the outer surface of a metal wire having a fluororesin coating with a dielectric barrier discharge is known from JP 11222530 A. An electrode is spirally wound around a tube made of a dielectric material. A metal wire is fed in one direction through the free cross-section of the tube, and an inert atmospheric gas is blown in the counter direction through the tube, the oxygen concentration of this gas being reduced to 500 ppm or less. The dielectric barrier discharge is generated between the metal wire being connected to ground and acting as a counter electrode, and the dielectric shielding of the electrode under atmospheric pressure to enhance the bonding properties of the fluororesin coating of the metal wire. JP 11222530 A does not refer to the problem to electrically ground the metal wire coated with the fluororesin.

An apparatus for treating the outer surface of a metal wire without a coating is known from SU 1362526 A1. Here, several ring-shaped electrodes are arranged on a tube made of dielectric material one behind the other in the direction of the tube axis. The electrodes are connected to different phases of a three phase high voltage alternating current generator. The zero phase of this alternating high voltage generator is connected to the metal wire guided on the tube axis. The metal wire is not only treated by the discharge between the dielectric shielding of the electrodes and its outer surface but also excited for vibrations by the applied alternating voltage which is tuned to its mechanical resonance frequency to shake coarse dirt off the metal wire. The suitable frequencies of the alternating high voltage to be applied to the electrodes with the alternating high voltage generator are thus rather below the typical frequency range for the excitation of a dielectric barrier discharge. SU 1362526 A1 does not refer to problems in electrically contacting the metal wire with the zero phase of the alternating high voltage generator.

### SUMMARY OF THE INVENTION

The present invention relates to an apparatus for treating the outer surface of a metal wire being moved through the apparatus along a direction of longitudinal extension of the metal wire, the apparatus having two electrodes arranged at a distance in the direction of longitudinal extension of the metal wire; a gas room being arranged between the outer surface of the metal wire to be treated and said electrodes; a dielectric shielding for said electrodes shielding said electrodes towards the metal wire; and an alternating voltage generator generating an alternating high voltage between said two electrodes to provide a dielectric barrier discharge in said gas room above the outer surface of the metal wire, the metal wire serving as an intermediate electrode between said two electrodes.

A dielectric barrier discharge, i.e. a gas discharge, may be maintained at atmospheric pressure with low technical efforts. The dielectric barrier discharge ensures a chemically active surrounding of the metal wire in the gas room which effectively cleans the metal wire from any lubricant remainders within very short time. Additionally, a surface activation takes place which has the result that a subsequently applied coating strongly bonds to the surface of the metal wire or its prior coating. Additionally, the metal wire or its prior coating is heated up by the discharge above its surface. This is no draw back; instead, a wire has not only to be cleaned from lubricant remainders and to be surface activated but also to be heated up to a defined temperature in the order of 250° C. for being coated with plastics, for example. All this is achieved with by the apparatus according to the invention in a single step.

When compared to a discharge without dielectric barrier, a dielectric barrier discharge additionally has the advantage that the maximum flowing currents are limited and that, thus, quite simple alternating voltage generators may be used.

In treating the surface of a metal wire having a not electrically conducting coating, the isolating coating around the metal wire may as such provide the dielectric shielding of the electrode with regard to the conductive metal wire. However, even in this case it is preferred, if an additional dielectric shielding is provided directly in front of the electrode, and thus on the other side of the gas room above the outer surface of the coating of the metal wire.

As already mentioned, the dielectric barrier discharge may take place at normal pressure. However, a certain over or under pressure may also be adjusted in the gas room. An overpressure of up to about 2.000 hPa is preferred. By means of this overpressure some kind of an air barrier system may be realized to avoid the introduction of volatile foreign matters into the gas room. Particularly, it can be achieved by an overpressure in the gas room that reaction products of the lubricant remainders are blown out of the gas room.

Such a blowing off the reaction products of the lubricant remainders out of the gas room can also be ensured in that an air flow is directed through the gas room. With a metal wire being conveyed through the gas room in one direction the flow of ambient air should be effected in the opposite direction to keep the occurring reaction products as far away as possible from the ready treated metal wire.

The alternating high voltage for generating the dielectric barrier discharge should be higher than 1 kV and will typically be several kV. Its frequency typically is in a range of 20 kHz up to 3 MHz.

With regard to the wire, the heating up by means of the discharge in the gas room is often advantageous as explained above. With regard to the electrode and its dielectric shielding, however, it is suitable to remove the occurring heat energy to avoid an overheating. This is preferably achieved in that the dielectric shielding of the electrode is cooled.

In an actual embodiment of the apparatus according to the invention the gas room has the shape of an elongated cylinder, the metal wire being arranged on the cylinder axis. The electrode and its dielectric shielding enclose the gas room like a cylinder jacket. The electrode may be wound spirally around the dielectric shielding. The metal wire is continuously conveyed through the gas room.

To ensure a sufficient removing of lubricant remainders from the surface of the metal wire, the dielectric barrier discharge may be intensified; it is also possible, however, to elongate the gas room or to arrange several gas rooms one behind the other around the metal wire. These parameters also have an influence on the temperature up to which the metal wire is heated up by the dielectric barrier discharge. By tuning these parameters it is possible to heat up the metal wire within the gas room up to a define temperature of above 200° C.

In the apparatus according to the invention the metal wire serves as a counter electrode for the electrode with the dielectric shielding so that the discharge occurs between the shielding and the surface of the metal wire or its coating, respectively. The alternating high voltage is generated by an alternating voltage generator having a floating output between two electrodes arranged at a distance in the direction of longitudinal extension of the metal wire, each electrode preferably having an own dielectric shielding. The metal wire connects the areas of both electrodes, and because of its conductivity, it serves as a counter electrode for both dielectrically shielded electrodes. It can thus be understood as an intermediate electrode in the middle between the two dielectrically shielded electrodes, on both sides of which gas rooms are formed in which dielectric barrier discharges occur.

In the apparatus according to the invention the gas room preferably surrounds the metal wire in all directions.

To remove reaction products out of the gas room, a source for pressurized air may be provided, which generates an airflow through the gas room. This air flow preferably has an opposite direction to the movement of the metal wire through the treatment room.

The alternating high voltage generator is preferably designed for an alternating voltage higher than 1 kV and a frequency of 20 kHz up to 3 MHz.

Preferably, a cooling arrangement is provided for the dielectric shielding of the electrode. To realize this cooling arrangement, the shielding may be two part, a free space between the two parts of the shielding being connected to a circulating device for a cooling liquid. This circulating device forwards a cooling liquid through the free space between the two parts of the shielding. The cooling liquid can be water. To reduce the electric conductivity of the water, it should be deionised or distilled water. Alternatively, the cooling liquid may be an oil, like, for example, a silicon oil.

The dielectric shielding of the electrode may include at least one tube. A two part shielding can be made of two tubes arranged one within the other at a distance, the distance between the two tubes defining the free space for the cooling liquid. In an arrangement of two tubes one within the other, between which a free space is formed for the cooling liquid, the electrode may also be arranged directly on the inner tube and thus within the cooling liquid so that only the inner tube forms the dielectric shielding of the electrode. The outer tube then not only defines the free space for the cooling liquid but also forms an outer isolation for the electrode.

Preferably, a guiding arrangement is provided for the metal wire which guides it on the tube axis. If the metal wire, however, is already oriented in a defined way by other means, like, for example, by neighbouring apparatuss, no additional guiding arrangement is necessary.

In a particularly preferred embodiment of the new apparatus, the gas room may be viewed through the electric shielding. In this way, it may be optically monitored whether the desired dielectric barrier discharge really takes place in the gas room. The transparency of the shielding may be realized in that it is made of glass, for example quartz glass. Water or silicon oil as the cooling liquid is also transparent to a sufficient extent. The transparency of the electrodes can be realized in that the electrodes are wound as a wire or ribbon having windings arranged at a distance onto its shielding.

If it is not necessary to view in the gas room of the new apparatus, the dielectric shielding can of course also be made of other materials than glass. Then, particularly ceramic materials, like for example aluminium oxide, may be used which show a high heat resistance besides their dielectric properties.

Other features and advantages of the present invention will become apparent to one with skill in the art upon examination of the following drawings and the detailed description. It is intended that all such additional features and advantages be included herein within the scope of the present invention, as defined by the claims.

### BRIEF DESCRIPTION OF THE DRAWINGS

The invention can be better understood with reference to the following drawings. The components in the drawings are not necessarily to scale, emphasis instead being placed upon clearly illustrating the principles of the present invention. In the drawings, like reference numerals designate corresponding parts throughout the several views.

FIG. 1 is a side view of an embodiment of the apparatus according to the invention.

FIG. 2 is a side view of the embodiment of the apparatus according to FIG. 1 treating a metal wire which is provided with a non conductive coating.

FIG. 3 is a side view of one of the electrodes of the apparatus according to FIG. 1.

FIG. 4 is a side view of one of the electrodes of the apparatus according to FIG. 1 together with an additional source for pressurized air.

FIG. 5 is a side view of one of the electrodes of another embodiment of the apparatus according to the invention; and

FIG. 6 is an enlarged cross section through the apparatus according to FIG. 5.

### DETAILED DESCRIPTION

Referring now in greater detail to the drawings, FIG. 1 illustrates an apparatus 10 for treating the surface of a metal wire 3. The apparatus 10 having two electrodes 4 and one dielectric shielding 2 consisting of one glass tube 11 for each electrode 4. Each of the units consisting of one electrode 12 and its dielectric shielding 2 can be formed according to any of the FIGS. 3 to 6. I.e. all variants which will be described with reference to these Figures can also be realised here. The apparatus 10 according to FIG. 1 is not limited to a series arrangement of two units as described with reference to the subsequent Figures. Instead, an alternating voltage generator 6 is not grounded but applies the alternating voltage between the two electrodes 4, i.e. the alternating voltage generator 6 has a floating output. In this way, it is possible to do without connecting the metal wire 3 to ground. The metal wire 3 acts as an intermediate electrode between the two electrodes 4, and is, thus, even without connection to ground a full value counter electrode for an respective discharge an respective compartment of a gas room 5. The conductivity for alternating currents is sufficient with all possible metal wires to bridge the distance of both electrodes 4 in the longitudinal direction of the metal wire 3. In the apparatus 10 according to the invention the metal wire may of course also be grounded to securely avoid the formation of charges on it. This does not affect the function of the apparatus 10 according to the invention. Here, however all problems with an insufficient connection to ground which may normally be caused by an isolating effect of impurities on the surface of the metal wire 3, for example, are avoided.

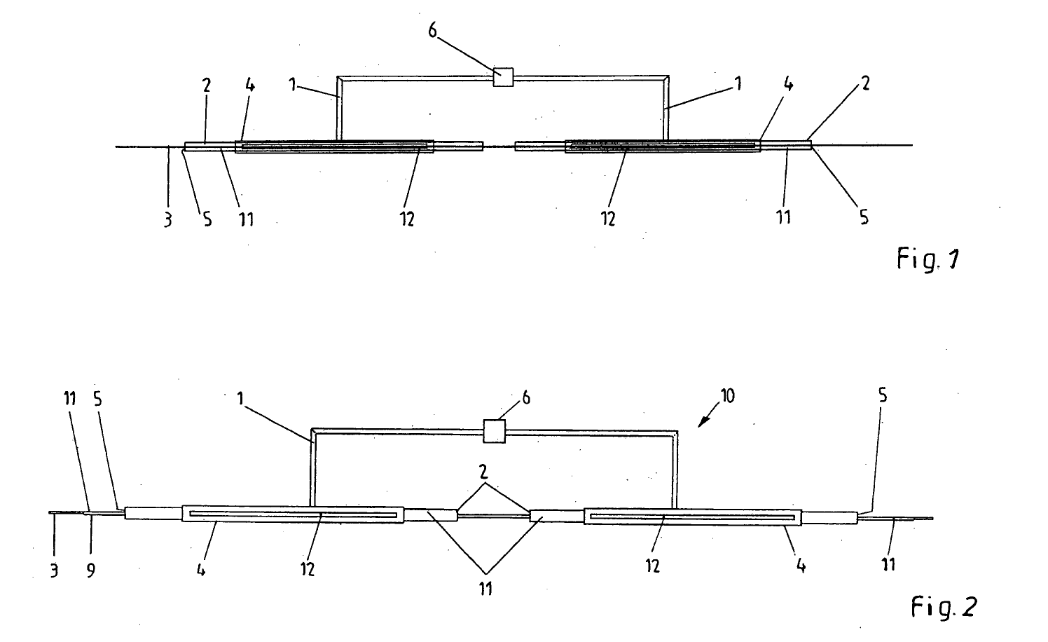

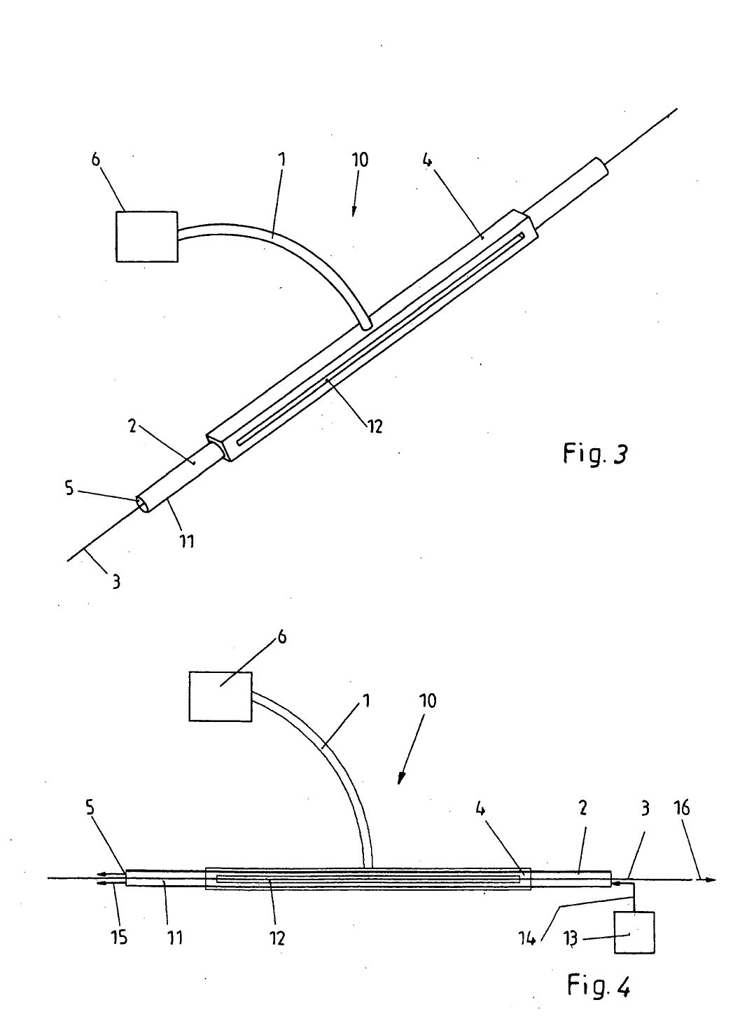

FIG. 2 shows the apparatus according to FIG. 1 in treating a metal wire 3 being provided with a prior coating 9. This can be done to prepare the outer surface of the metal wire 3 which actually is the surface of the prior coating 9 for printing on it with an inkjet printer which is not depicted here, for example, so that the ink adheres to the outer surface better and for a longer term. The function of the apparatus 10 in treating the coated metal wire 3 according to FIG. 2 is principally the same as in treating the not coated metal wire 3 according to FIG. 1. The only difference is to be seen in that a not electrically conductive coating 9 on the metal wire 3, i.e. an isolating layer, acts as an additional dielectric shielding 11 of the electrodes 4 with regard to the metal wire 3.

All of the embodiments of the apparatus 10 described here result in an all side treatment of the outer surface of the metal wire 3 or its prior coating 9, respectively.

The gas atmosphere in the gas room 5 in which the dielectric barrier discharge is generated can be simple ambient air. To increase the cleaning effect, pure oxygen or other reaction gases may be added. Noble gases may also be added to enhance the activation of the surface of the metal wire 3 for a subsequent coating.

In the apparatus 10 which will now be further described with reference to FIG. 3, the metal wire 3 is guided through the glass tube 11 in the area of the tube axis of the glass tube. A gas room 5 is arranged between the surface of the metal wire 3 and the inner surface of the glass tube 11, which contains air. Reaction or noble gases may be added to the air, but this is not necessary. An electrode 4 made of solid copper or stainless steel, for example, is arranged directly on the glass tube 11, no gaps being present between the electrode 4 and the gas tube 11. The electrode 4 is provided with an opening 12 to view into the gas room 5 through the glass tube 11 even in the region of the electrode 12. The electrode 4 is connected, via a high voltage supply line 1 to the alternating voltage generator 6 which generates a alternating high voltage in the range of several kV and having a typical frequency of several 100 kHz. The alternating field resulting in the gas room 5 generates a discharge within the gas room 5. This discharge is a dielectric barrier discharge as the glass tube 11 serves as a dielectric shielding 2 of the electrode 4. By means of the dielectric barrier discharge in the gas room 5, it is avoided that higher currents locally flow through the gas room 5, i.e. it is avoided that an arc discharge and thus a short circuit of the electrode 4 to the metal wire 3 occurs. Thus, the discharge is stabilized over the volume of the gas room 5, and the alternating voltage generator 6 is subject to lower requirements than in a case in which arc discharges take place. Nevertheless, the discharge in the gas room 5 results in an reactive environment around the metal wire 3 to remove lubricant remainders and the like adhering to the surface of the metal wire 3, i.e. to oxygenize them essentially to CO₂ and water. Additionally, the surface of the metal wire is activated, and the metal wire is heated up so that it is all at all fully pre-treated for a plastic coating which requires a cleaned and heated up metal wire with an activated surface.

FIG. 4 shows a side view of the parts of the apparatus 10 depicted in FIG. 3 in a perspective view, a source for pressurized air 13 being additionally indicated, by which pressurized air 14 can be blown into the gas room 5 to generate an air flow 15 through the gas room 5. This air flow 15 preferably flows in a counter direction to the movement of the metal wires 3 through the gas room 5 in a direction of an arrow 16. By means of the air flow 15 any oxidation remainders from the oxidation of the surface impurities of the metal wire 5 or any inert particles removed from there can also be blown out of the glass tube 11, which could otherwise affect a controlled discharge within the gas room 5.

In testing the apparatus according to FIGS. 1, 3 and 4, the glass tube 11 had an inner diameter of 6 mm. Its length was 400 mm, and it was extending on both sides by more than 50 mm beyond the electrode 4. Using an alternating voltage generator 6 on a semiconductor basis having an efficiency of 90% with a high voltage of high frequency, the dielectric barrier discharge could be ignited and maintained with diameters of the metal wire from 0.6 to 1.3 mm without any problems. The desired cleaning of the surface of the metal wire could be achieved within very short time, i.e. actually even with conveying speeds of the metal wire 3 of clearly above 1 m/s and even up to 5 m/s. Heating up also occurred fast, the heating up naturally decreasing with increasing diameter of the metal wire. A following plastic coating of the metal wire pre-treated in this way resulted in excellent bonding properties of the coating plastic.

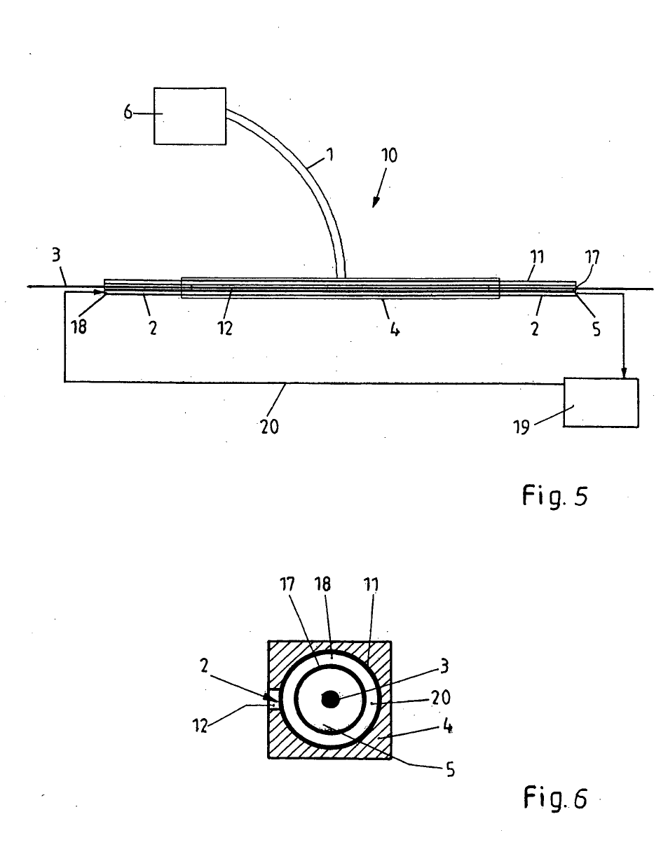

FIGS. 5 and 6 show parts of an embodiment of the apparatus 10 which is varied with regard to FIGS. 3 and 4 in that a further glass tube 17 is arranged within the glass tube 11 coaxially to the glass tube 11 and the metal wire 3. A cylinder jacket shaped free space 18 is remaining between the glass tubes 11 and 17. A circulating device 19 circulates a cooling liquid 20 through the free space 18 to cool the dielectric shielding 2 of the electrode 4. Whereas heating up the metal wire 3 is desired and may be adjusted, i.e. limited, to a certain extent with the metal wire 3 being conveyed through the apparatus 10, heating the dielectric shielding 2, which actually consists of the glass tubes 11 and 17 as well as the cooling liquid 10 in the free space 18, up to more than a certain extent is not desired. Particularly those cooling liquids may be used which have no relevant electric conductivity, like, for example distilled water or silicon oil.

Many variations and modifications may be made to the preferred embodiments of the invention without departing substantially from the spirit and principles of the invention. All such modifications and variations are intended to be included herein within the scope of the present invention, as defined by the following claims.

1. An apparatus for treating the outer surface of a metal wire being moved through the apparatus along a direction of longitudinal extension of the metal wire, the apparatus having:
two electrodes arranged at a distance in the direction of longitudinal extension of the metal wire;
a gas room being arranged between the outer surface of the metal wire to be treated and said electrodes,
a dielectric shielding for said electrodes shielding said electrodes towards the metal wire; and
an alternating voltage generator generating an alternating high voltage between said two electrodes to provide a dielectric barrier discharge in said gas room above the outer surface of the metal wire, the metal wire serving as an intermediate electrode between said two electrodes.

2. The apparatus of claim 1, wherein said dielectric shielding is arranged directly in front of said electrodes.

3. The apparatus of claim 1, wherein a source for pressurized air is provided for creating an air flow through said gas room in parallel to the direction of longitudinal extension of the metal wire.

4. The apparatus of claim 2, wherein said source for pressurized air is provided for creating the air flow through said gas room in a direction opposite to the direction of longitudinal extension of the metal wire in which the metal wire is moved through the apparatus.

5. The apparatus of claim 1, wherein said alternating voltage generator has a floating output.

6. The apparatus of claim 1, wherein said alternating voltage generator is designed for generating an alternating high voltage of more than 1 kV and having a frequency in the range of 20 kHz to 3 MHz.

7. The apparatus of claim 1, wherein a cooling apparatus is provided for cooling said dielectric shielding of said electrodes.

8. The apparatus of claim 5, wherein said cooling apparatus for cooling said dielectric shielding comprises two tubes arranged one within the other, a free space remaining between said two tubes, and being connected to a circulating apparatus for circulating a cooling liquid through said free space.

9. The apparatus of claim 1, wherein the electrodes and their shielding are transparent so that the gas room may be viewed through the electrodes and their dielectric shielding.

10. The apparatus of claim 1, wherein said dielectric shielding of said electrode comprises two parts separated from each other in the direction of longitudinal extension of the metal wire, each of said two parts of said dielectric shielding enclosing one compartment of the gas room.

11. An apparatus for treating the outer surface of a metal wire being moved through the apparatus along a direction of longitudinal extension of the metal wire, the apparatus having:
two electrodes arranged at a distance in the direction of longitudinal extension of the metal wire;
a gas room being arranged between the outer surface of the metal wire to be treated and said two electrodes, one compartment of said gas room being arranged between the outer surface of the metal wire to be treated and each of said two electrodes,
a dielectric shielding arranged directly in front of said electrodes, one separate part of said dielectric shielding shielding each of said two electrodes towards the metal wire and enclosing one of said compartments of the gas room; and
an alternating voltage generator having a floating output generating an alternating high voltage of more than 1 kV and at a frequency in the range of 20 kHz to 3 MHz between said two electrodes to provide a dielectric barrier discharge in said gas room above the outer surface of the metal wire, the metal wire serving as an intermediate electrode between said two electrodes.

12. The apparatus of claim 10, wherein a cooling apparatus is provided for cooling said dielectric shielding of said electrodes, said cooling apparatus comprising two tube sections arranged one within the other per each of said two electrodes, a free space remaining between said two tube sections, and being connected to a circulating apparatus for circulating a cooling liquid through said free space.
